(19) United States
(12) Patent Application Publication
(10) Pub. No.: US 2017/0147730 A1
(43) Pub. Date: May 25, 2017

(54) BINARY PATTERNING FOR THREE-DIMENSIONAL MEMORY FORMATION

(71) Applicant: Apple Inc., Cupertino, CA (US)

(72) Inventor: Assaf Shappir, Herzliya Pituach (IL)

(21) Appl. No.: 14/948,407

(22) Filed: Nov. 23, 2015

(51) Int. Cl. G06F 17/50; H01L 27/115

(52) U.S. Cl. CPC G06F 17/5068; H01L 27/11551; H01L 27/11578

(57) ABSTRACT

A method for designing a patterning process for a three-dimensional (3D) memory includes defining a target 3D structure of the 3D memory, to be applied in a periodic structure of layers on a substrate. The target 3D structure is converted into a sequence of multiple steps, each step specifying a respective pattern to be removed and a respective number of the layers to be removed from the periodic structure under the respective pattern. The sequence of steps is sent to one or more manufacturing tools.

### TECHNICAL FIELD

Embodiments described herein relate generally to memory devices, and particularly to methods and systems for manufacturing of three-dimensional memory devices.

### BACKGROUND

Memory devices can be configured in two-dimensional (2D) or three-dimensional (3D) structures, which typically require different manufacturing methods. Various techniques for manufacturing memory devices having a 3D structure are known in the art.

For example, U.S. Pat. No. 8,759,217, whose disclosure is incorporated herein by reference, describes a method for forming interlayer connectors extending to conductive layers of a stack of W conductive layers interleaved with dielectric layers. The stack is etched to expose landing areas at W-1 conductive layers using a set of M etch masks. For each etch mask m, m going from 0 to M-1, there is a first etching step, at least one mask trimming step, and a subsequent etching step following each trimming step.

U.S. Pat. No. 8,598,032, whose disclosure is incorporated herein by reference, describes a three-dimensional stacked IC device that has a stack of contact levels at an interconnect region. According to some examples, only a set of N etch masks is required to create up to and including 2N levels of interconnect contact regions at the stack of contact levels.

U.S. Pat. No. 8,633,099, whose disclosure is incorporated herein by reference, describes a method for forming interlayer connectors in a three-dimensional stacked IC device. Contact openings are created through a dielectric layer to a first conductive layer. N etch masks, with 2N-1 being less than W, and 2N being greater than or equal to W, have spaced apart open etch regions and mask regions elsewhere.

### SUMMARY

An embodiment that is described herein provides a method for designing a patterning process for a three-dimensional (3D) memory, including defining a target 3D structure of the 3D memory, to be applied in a periodic structure of layers on a substrate. The target 3D structure is converted into a sequence of multiple steps, each step specifying a respective pattern to be removed and a respective number of the layers to be removed from the periodic structure under the respective pattern. The sequence of steps is sent to one or more manufacturing tools.

In some embodiments, the periodic structure includes two or more layers, at least two of the layers of the periodic structure differing in material composition. In other embodiments, the periodic structure includes two or more layers, at least two of the layers of the periodic structure differing in material thickness. In an embodiment, at least two of the steps in the sequence specify different respective patterns. In another embodiment, at least two of the steps in the sequence specify different respective numbers of the layers to be removed.

In some embodiments, the method further includes defining a reference target 3D structure having a respective reference sequence of multiple steps designed for producing the reference target 3D structure. Converting the target 3D structure may include changing one or more properties of the steps of the reference sequence. In some embodiment, changing the one or more properties includes at least one of reordering the steps in the reference sequence, modifying the pattern to be removed in at least one step in the reference sequence, and changing the number of the layers to be removed in at least one step in the reference sequence.

In other embodiments, the layers of the periodic structure implement multiple memory arrays. In an embodiment, the target 3D structure includes a staircase structure including multiple stair steps, at least one of the stair steps including at least one electrical contact, which is configured to connect between a respective memory array and a peripheral circuit. In yet other embodiments, the numbers of the layers to be removed form a sequence of powers of two.

There is additionally provided, in accordance with an embodiment that is described herein, a system for designing a patterning process for a three-dimensional (3D) memory including an interface and a processor. The interface is configured to exchange information with one or more manufacturing tools. The processor is configured to define a target 3D structure of the 3D memory, to be applied in a periodic structure of layers on a substrate, to convert the target 3D structure into a sequence of multiple steps, each step specifying a respective pattern to be removed and a respective number of the layers to be removed from the periodic structure under the respective pattern, and to send, via the interface, the sequence of steps to the one or more manufacturing tools.

There is further provided, in accordance with an embodiment that is described herein, a non-transitory computer-readable medium including instructions that, when executed by one or more processors, cause the one or more processors to perform a method for designing a patterning process for a three-dimensional (3D) device. The method includes defining a target 3D structure of the 3D device, to be applied in a periodic structure of layers on a substrate, converting the target 3D structure into a sequence of multiple steps, each step specifying a respective pattern to be removed and a respective number of the layers to be removed from the periodic structure under the respective pattern, and sending the sequence of steps to one or more manufacturing tools.

These and other embodiments will be more fully understood from the following detailed description of the embodiments thereof, taken together with the drawings in which:

### BRIEF DESCRIPTION OF THE DRAWINGS

FIG. 1 is a block diagram that schematically illustrates a system for designing a patterning process for manufacturing a three-dimensional (3D) memory, in accordance with an embodiment that is described herein;

FIGS. 2A and 2B are schematic sectional views of a sequential process for patterning a 3D memory structure, in accordance with an embodiment that is described herein; and

FIG. 3 is a flow chart that schematically illustrates a method for patterning a 3D memory, in accordance with an embodiment that is described herein.

### DETAILED DESCRIPTION OF EMBODIMENTS

### Overview

Memory devices are used in various storage applications and required to provide high storage capacity at affordable cost. The structure of a memory may be planar as in traditional two-dimensional (2D) memory devices, or vertical as, for example, in three-dimensional (3D) Flash memory structures. The usage of 3D memory devices is driven, at least in part, by the demand for increased memory density. The manufacturing costs of 3D memory structures are typically high, which increases the cost of the end product compared to using 2D memories.

Embodiments of the present invention that are described herein provide improved methods and systems for designing a patterning process of 3D memory devices. In some embodiments, the disclosed techniques include defining a target 3D structure of the 3D memory, to be applied in a periodic structure of layers on a substrate, and designing a sequential process for forming this target structure. Each step in the process specifies a pattern to be removed and a respective number of the layers to be removed from the periodic structure under the respective pattern. The designed sequence of steps is sent to one or more manufacturing tools for executing the sequence and forming the target 3D structure of the 3D memory.

In other embodiments, the sequential process enables “binary” removal of stacks in the periodic structure, i.e., a process in which the number of stacks of layers removed at a given step is a power or two. Accordingly, this selection allows to remove all possible numbers of stacks and layers using a minimal number of steps. For example, a four-step process of 1, 2, 4 and 8-stack removals is able to etch any number of stacks from zero to 15 in just four steps.

The target 3D structure may comprise a staircase, of which each stair is formed in a periodic stack of the structure and provides an electrical contact to a respective array of memory cells. Each periodic stack comprises two or more layers. At least two of the layers within the stack differ from one another with respect to the material composition from which the layers are made and/or the thickness of the layers. In some embodiments, at least two steps of the sequential process assign different respective patterns. In yet other embodiments, the number of layers to be removed under the specified pattern may differ between at least two respective steps of the sequence.

In an embodiment, a certain target 3D structure serves as a reference structure. The reference is manufactured using a reference sequence of multiple steps. The reference target 3D structure may be modified by changing the order of the sequence of steps, so as to produce a different target 3D structure. In yet another embodiment, the shape of the 3D structure may be controlled by changing the specified respective pattern to be removed in at least one of the steps. Alternatively or additionally, the shape of the 3D structure may be controlled by changing the specified respective number of the layers to be removed in at least one of the steps.

The techniques described above may simplify the patterning process flow by designing a patterning process that has a reduced number of patterning steps and sub-steps, thus reducing manufacturing costs. Furthermore, each step of the sequence may be used as a separate design module for patterning. A designer may apply the design modules in a suitable order to form a desired 3D structure. This modular approach may improve the electrical performance and reduce the manufacturing costs of 3D memory devices.

### System Description

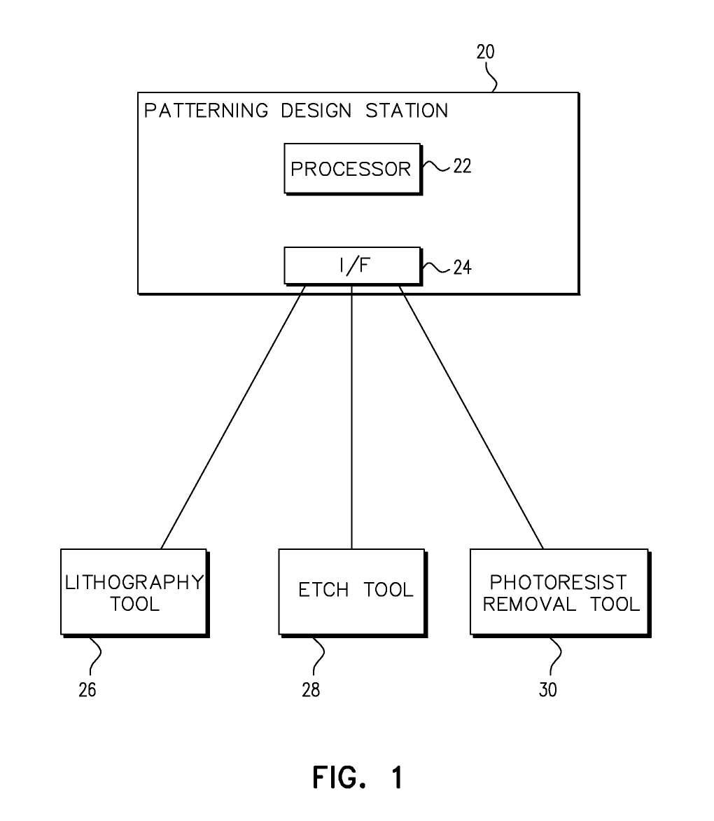

FIG. 1 is a block diagram that schematically illustrates a system 20 for designing a patterning process for manufacturing a three-dimensional (3D) memory, in accordance with an embodiment that is described herein.

System 20 comprises a processor 22, which is configured to define a target 3D memory structure or to receive the target 3D memory structure from an external source, such as a host computer (not shown), and to design for the target structure a sequential patterning process sequence comprises multiple patterning steps. The memory structure typically comprises multiple substantially similar stacks of layers. Each stack may comprise two or more layers that may have different material composition, thickness and electrical properties.

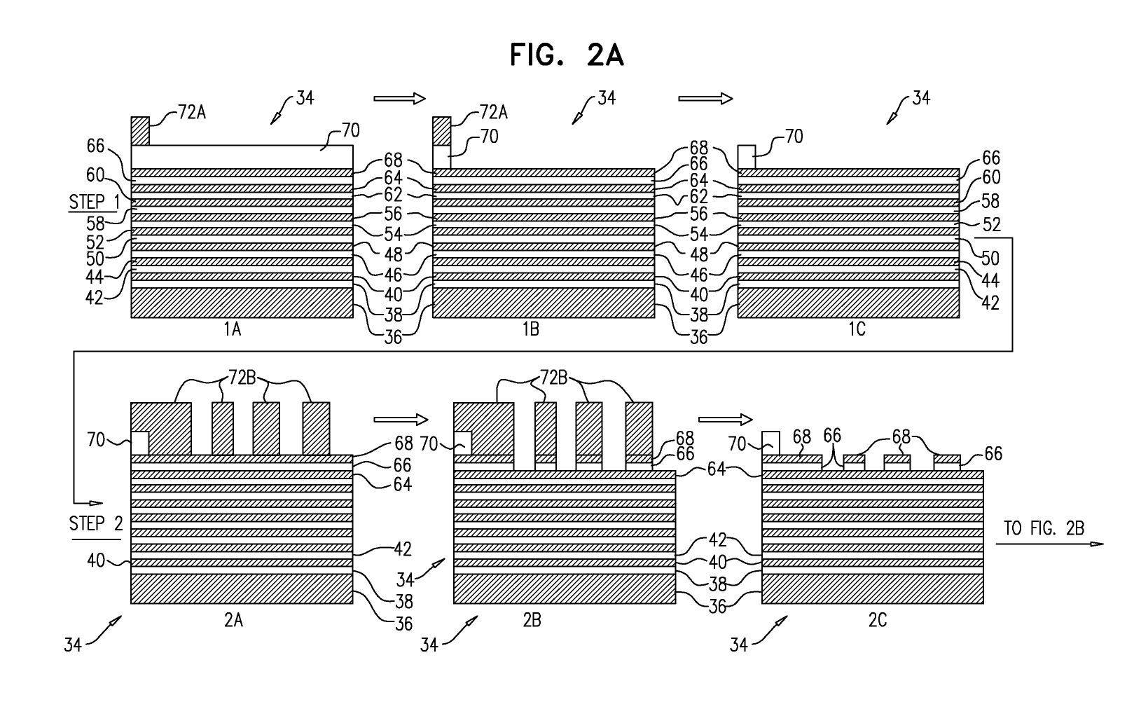

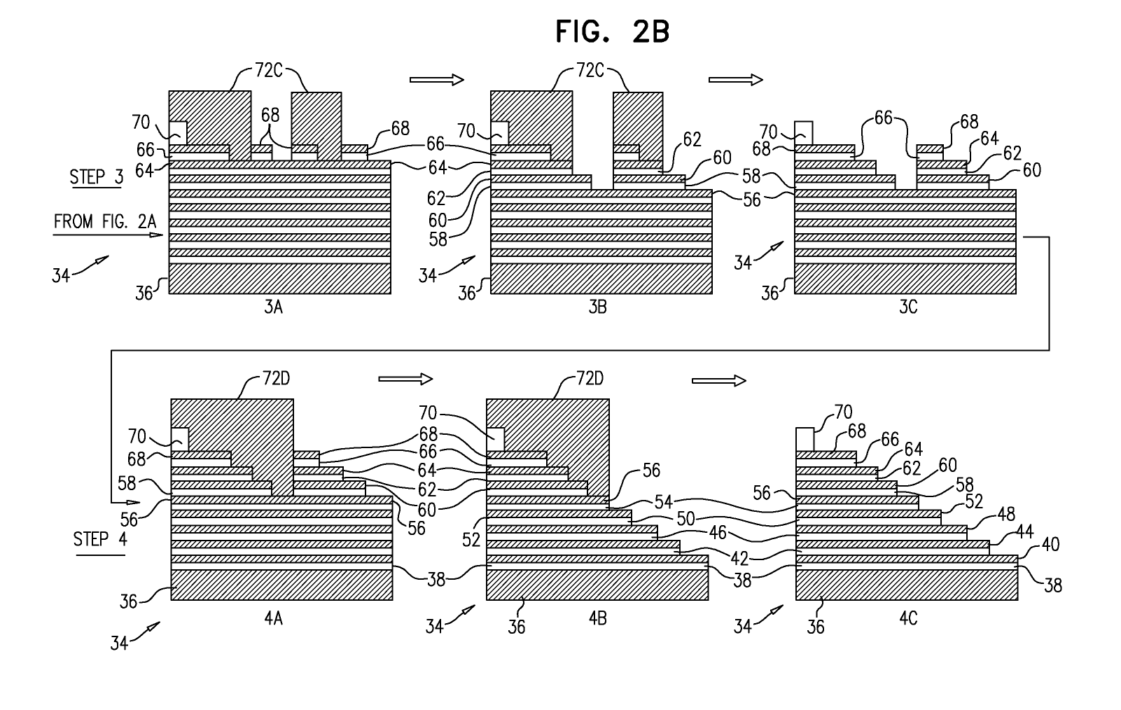

The thickness of each layer is typically on the order of nanometers or tens of nanometers, but the thicknesses may range between several angstroms to several microns. Each patterning step comprises at least two sub-steps, of which the first sub-step specifies a pattern to be removed from the structure, and the second sub-step specifies the number of layers to be removed under the respective pattern. The pattern and number of layers to be removed typically differ among different steps as described in detail in FIGS. 2A and 2B.

In some embodiments, processor 22 comprises a general-purpose processor, which is programmed in software to carry out the functions described herein. The software may be downloaded to the processor in electronic form, over a network, for example, or it may, alternatively or additionally, be provided and/or stored on non-transitory tangible media, such as magnetic, optical, or electronic memory.

System 20 further comprises an interface 24, which receives the patterning process sequence from processor 22 and sends each sub-step of the sequence to a respective manufacturing tool, such as a lithography tool 26, an etching tool 28 and a photoresist removal tool 30. In this example, the first sub-step may be sent to lithography tool 26, which is configured to set the specified pattern on the surface of the memory structure. The second sub-step may be sent to etch tool 28, which is configured to remove (typically by etching) the specified number of layers under the specified pattern.

The number of process tools is typically larger than three due to the broad capabilities required for patterning the 3D memory structure. In the present example, tool 30 may be used to remove photoresist residues after the etching process applied by tool 28, and a fourth tool (not shown) may be used to prepare the surface for subsequent processing steps.

In some embodiments, after the tool completes executing a given sub-step, the tool sends a process completion notice to processor 22 via interface 24. In response to receiving the completion notice, the processor sends a command to one of the tools, to execute the next sub-step in the sequence.

The specific tools shown in FIG. 1 are depicted purely by way of example. In alternative embodiments, system 20 may operate in conjunction with any other suitable manufacturing tools.

### Array Fanout in 3D Memory Structures

Memory devices such as NAND Flash devices typically comprise memory arrays that each comprises multiple memory cells, and peripheral circuits connecting to the memory arrays. A 3D memory array exploits a third dimension of multilayer stacks so as to increase the array's density and its storage capacity. The peripheral circuits connecting to the memory arrays typically comprise two-dimensional (2D) structures. One way for connecting the vertical multilayer stacks of 3D NAND cells to the peripheral circuits requires patterning a complex staircase structure (or any alternative suitable 3D structure) in the 3D array. The staircase structure allows separate routing of every layer of the memory array to one or more peripheral circuits. Such fan-out routing typically comprises plugs, such as contacts and vias. Each plug connects between a level (stair step) of the staircase structure and a respective conducting metal line comprised in the 2D circuits located above the upper surface (or below the lower surface) of the 3D structure. Typically, processing techniques such as photolithography, planarization, anti-reflective coating (ARC) and etching, are used for patterning each multilayered stack so as to form the desired staircase structure. For the sake of clarity, the description below refers mainly to 3D patterning using photolithography and etching processes. The disclosed techniques, however, are equally applicable to patterning using other suitable processes as described above.

Typically but not necessarily, the storage capacity of a 3D memory array increases with the number of stacks comprising the array. For example, given a stack that has a storage capacity of one billion bits (1 gigabit), a multilayered structure comprising 32 such stacks has a storage capacity of up to 32 gigabits. Patterning a structure of multilayered stacks typically requires a separate processing cycle for each stack, i.e., 32 processing cycles in the example of 32 stacks.

Furthermore, future NAND memory devices may use over 128 stacks, which further increases the complexity and cost of patterning such staircase structures. The disclosed techniques provide design methods for efficient patterning of staircase structures in multilayered stacks of 3D memory devices.

FIG. 2A is a schematic sectional view of a first part of a sequential process for patterning a 3D memory structure 34, in accordance with an embodiment that is described herein. Memory structure 34 comprises a substrate 36, typically made of silicon or another suitable semiconductor material such as germanium or gallium-arsenide.

Structure 34 further comprises multiple substantially similar stacks, each comprising one or more layers. In the example of FIG. 2A, structure 34 comprises eight (8) stacks that each comprises two layers, i.e., a total of 16 layers, denoted 38-68. The first (lowest) stack comprises layer 38 that is formed on substrate 36 and layer 40 that is formed on layer 38. Layer 68 is the top layer of the eighth stack. While structure 34 is referred to as a 3D memory structure 34, the embodiments are not so limited and structure 34 may correspond to any 3D structure in a device having a similar structure and/or composition that can be formed by the manufacturing processes described herein.

Layer 38 typically comprises a different material composition, thickness and electrical properties compared to layer 40. For example, layer 38 may comprise an insulating material, such as silicon-oxide (Ox), whereas layer 40 may comprise a conducting material, such as tungsten (W). Similarly, the second stack comprises a silicon-oxide layer 42, and a tungsten layer 44. This structure repeats in the remaining third to eighth stacks, wherein each double-layer stack implements a plane of memory cells. The structure of double-layer stacks presented in FIGS. 2A and 2B is provided by way of example, and in alternative embodiments any other suitable structure of stacks and layers can also be used.

In the example of FIGS. 2A and 2B, each of the stacks comprises two layers. Alternatively, each stack may comprise any suitable number of layers, and the layers within each stack may comprise any suitable materials, such as poly silicon, nitride and silicon carbide, according to the type of memory cell. An insulating layer 70, made of one or more insulating materials such as silicon-oxide, silicon-nitride or silicon oxy-nitride, is formed on top of layer 68, so as to assist in the manufacturing flow, by allowing planarization, surface cleaning, alignment and inspection steps, without impacting the active layers below, and to protect structure 34 from mechanical damage or contaminants before the patterning process begins.

Referring to a step 1, which comprises sub-steps 1A, 1B and 1C. At sub-step 1A, layer 70 is partially removed so as to expose part of layer 68, which is the uppermost layer. In an embodiment, a coat of photoresist 72A is formed on layer 70 using photolithography techniques. The term “photolithography techniques” refers to pattern definition techniques, such as hard mask formation, multiple patterning and other suitable techniques. Such techniques may use additional materials, such as insulating materials used in layer 70.

The surface of layer 70 not covered by photoresist 72A, is denoted a first pattern. At sub-step 1B, layer 70 is etched below the first pattern, and at a sub-step 1C, photoresist 72A is removed from the surface of layer 70 using photoresist asking (e.g., burning using downstream plasma) and other suitable techniques to remove residues from the surface of layer 68.

After step 1, the top surface of structure 34 comprises layer 68 under the first pattern and layer 70 covering layer 68 on the remaining area of the top surface of structure 34. In an alternative embodiment, layer 70 may be removed from the entire area of structure 34 using other techniques such as wet etching.

Referring to a step 2, at a sub-step 2A a photoresist 72B (and possibly anti-reflective coating) is formed on layers 70 and 68, so as to set a second pattern in the area not covered by the photoresist. In the example of sub-step 2A, the area under the second pattern comprises only layer 68 while layer 70 is entirely covered by photoresist 72B. At a sub-step 2B, layers 68 and 66 are etched under the second pattern using a two-stage etching process. In each stage, suitable chemical agents are used for etching the material of the respective layer. For example, carbon-fluoride agents may be used for etching the tungsten layer in the first stage and hydro-fluoric agents may be used for etching the oxide layer in the second stage. The use of different chemical agents allows high selectivity in the etching process, i.e., removing only the target layer without undesirably etching other layers of structure 34.

At a sub-step 2C, photoresist 72B is removed from the top surfaces of layers 68 and 70. At the end of step 2, the top surface of structure 34 comprises three levels; Layer 70 at the highest level, layer 68 at the middle level, and layer 66 at the lowest level. Etching step 1B comprises etching a single silicon-oxide layer while etching step 2B comprises etching two layers, i.e., 68 and 66, which are made of tungsten and silicon-oxide, respectively.

FIG. 2B is a schematic sectional view of a second part of the sequential process for patterning 3D memory structure 34, in accordance with an embodiment that is described herein. A step 3 comprises three sub-steps 3A, 3B and 3C. At step 3A, a photoresist 72C is formed on the top surface of structure 34 so as to set a third pattern with no photoresist on partial area of layers 68 and 66. At sub-step 3B, four layers (68, 66, 64 and 62) under the third pattern are etched using a four-stage etching sequence, W-Ox-W-Ox. The first and third stages apply a tungsten etching process for etching layers 68 and 64, respectively, and the second and forth stages apply an oxide etching process for etching layers 66 and 62, respectively.

The four-stage etching process may be carried out within a single processing chamber using alternating chemical agents for tungsten and oxide etching, or within multiple etching process chambers that each is used separately for tungsten or oxide etching. Additional processes, such as cleaning and annealing, may be incorporated in the four-stage etching process. In some embodiments, four layers belonging to two stacks are etched (under the third pattern) at sub-step 3B, using a single photolithography sub-step. In other embodiments, any other suitable number of layers and stacks may be etched under a given pattern set by a single photolithography sub-step. For example, in a 3D memory structure that comprises 128 stacks, over 64 stacks and a few hundreds of respective layers may be etched under a single pattern that was formed using a single photolithography sub-step. At sub-step 3C, photoresist 72C is removed from the top surface of structure 34. After step 3 terminates, structure 34 comprises two neighboring structures of staircases adjacent to one another. The left staircase comprises layers 56-70, and the right staircase comprises layers 56-68.

Following step 3, the process continues to a step 4, which comprises three sub-steps 4A, 4B and 4C. At sub-step 4A, a photoresist 72D is formed on the top surface of the left staircase, covering the patterned layers 54-70. The right staircase, denoted a forth pattern, comprises patterned layers 58-68, and un-patterned layers 38-56 located below the area of the right staircase.

At sub-step 4B, the forth pattern is etched so that the entire structure of the staircase is maintained and transferred from layers 56-68 to layers 40-52, respectively. For example, an upper stair step of the right staircase that comprises patterned layers 66 and 68 before applying sub-step 4B, is transferred to layers 50 and 52 while maintaining the same height and width of the upper level stair step. Sub-step 4B comprises etching of four tungsten layers and four oxide layers, carried out alternately, using a single photolithography sub-step.

After etching the forth pattern, photoresist 72D is removed at sub-step 4C using techniques as described at sub-steps 1C, 2C and 3C. At the end of sub-step 4C, a complete eight-level staircase structure is formed. The staircase comprises a substantially similar level (e.g., height and width) for each stack and its corresponding layers.

The sequential process described in FIGS. 2A and 2B forms the eight-level staircase structure by etching 7 stacks, using 3 patterning steps (steps 2-4). A single stack is patterned at step 2, two stacks are patterned at step 3, and 4 stacks are patterned at step 4.

As depicted in FIGS. 2A and 2B, the sequence allows “binary” removal of stacks. The term “binary” removal means that the numbers of stacks removed in the various steps forms a sequence of powers of two. A sequence of powers of two allows to remove all possible numbers of stacks with a minimal number of steps. For example, a four-step process of 1, 2, 4 and 8-stack removals is able to etch any number of stacks from zero to 15 (i.e., achieve a target 3D structure having sixteen possible heights) with only four steps.

In other embodiments, the binary removal of stacks may be applied in conjunction with removing any number of layers that may not comprise a full stack. For example, at step 1 the sequence allows removal of a single layer (layer 70), while steps 2-4 remove one or more complete stacks, each. The shape of the pattern and the number of patterned stacks per step is provided by way of example, and any other suitable number of stacks, pattern shape, number of patterned stacks per step and number of etched layers per step can also be used.

Furthermore, structure 34 may comprise any reference target 3D structure that comprises a respective reference sequence of multiple steps that are designed for producing the reference target 3D structure. In an embodiment, the steps order of the respective reference sequence may be modified in order to modify the reference target 3D structure, so as to optimize electrical performance and/or manufacturing costs of structure 34. For example, a process of etching 7 stacks may be carried by a three-step sequence that includes etching 2 stacks at a first step, followed by etching 4 stacks at a second step, and etching a single stack at a third step. In other embodiments, any suitable number of stacks etched per step and any suitable combination of etching steps may be used to optimize the electrical performance and/or the manufacturing cost of forming a target 3D geometry of structure 34 or any other 3D memory structure. Further, although the embodiments described herein have been specific to the manufacture of a 3D memory structure such as 3D memory structure 34, the embodiments may be used for the manufacture of any device having a 3D structure that is formed similar to 3D memory structure 34.

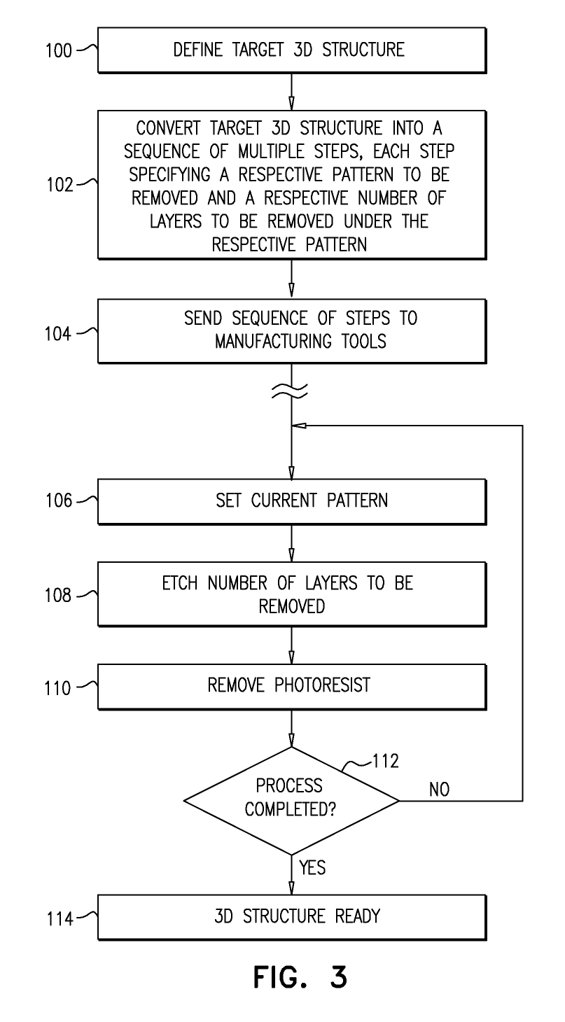

FIG. 3 is a flow chart that schematically illustrates a method for patterning 3D structures such as 3D memory structure 34, in accordance with an embodiment that is described herein. The method begins with processor 22 defining or receiving a target 3D structure for a 3D device such as a 3D memory that comprises multiple stacks that are substantially similar, each stack comprising a multilayered structure, at a structure definition step 100.

At a conversion step 102, processor 22 converts the target 3D structure into a sequence of multiple process steps. Each step specifies a pattern to be removed and a number of layers to be etched under the respective pattern. The shape of the pattern to be removed and the number of the layers to be removed typically differs from one step to another. At a sequence transfer step 104, processor 22 sends the process steps via interface 24 to respective manufacturing tools for executing the patterning process of the 3D structure according to the sequence.

At a pattern setting step 106, the structure, for example, structure 34 is inserted into a manufacturing tool (e.g., tool 26) that receives the designed pattern setting step (e.g., sub-step 1A) from interface 24 and sets a respective pattern on the top surface of structure 34, using a photoresist material (e.g., photoresist 72A). At an etching step 108, structure 34 is inserted into a second manufacturing tool (e.g., tool 28), which receives the designed etching step (e.g., sub-step 1B) from interface 24. One or more layers under the respective pattern, which are not covered by photoresist 72A, are etched using tool 28. At a photoresist removal step 110, structure 34 is inserted into a third manufacturing tool (e.g., tool 30) so as to remove photoresist 72A from the surface, as depicted at sub-step 1C for example.

At a decision step 112, processor 22 checks whether structure 34 has completed the entire sequence of the process steps. If the sequence is not completed, the method loops back to pattern setting step 106 to apply subsequent patterning steps. After the sequence is completed, structure 34 is substantially similar to the target 3D structure and the process is completed, at a structure completion step 114, which is the final step of the method.

It will be appreciated that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. A method for designing a patterning process for a three-dimensional (3D) memory, the method comprising:
defining a target 3D structure of the 3D memory, to be applied in a periodic structure of layers on a substrate;
converting the target 3D structure into a sequence of multiple steps, each step specifying a respective pattern to be removed and a respective number of the layers to be removed from the periodic structure under the respective pattern; and
sending the sequence of steps to one or more manufacturing tools.

2. The method according to claim 1, wherein the periodic structure comprises two or more layers, and wherein at least two of the layers of the periodic structure differ in material composition.

3. The method according to claim 1, wherein the periodic structure comprises two or more layers, and wherein at least two of the layers of the periodic structure differ in material thickness.

4. The method according to claim 1, wherein at least two of the steps in the sequence specify different respective patterns.

5. The method according to claim 1, wherein at least two of the steps in the sequence specify different respective numbers of the layers to be removed.

6. The method according to claim 1, wherein defining the target 3D structure further comprises defining a reference target 3D structure having a respective reference sequence of multiple steps designed for producing the reference target 3D structure, and wherein converting the target 3D structure comprises changing one or more properties of the steps of the reference sequence.

7. The method according to claim 6, wherein changing the one or more properties comprises at least one of reordering the steps in the reference sequence, modifying the pattern to be removed in at least one step in the reference sequence, and changing the number of the layers to be removed in at least one step in the reference sequence.

8. The method according to claim 1, wherein the layers of the periodic structure implement multiple memory arrays, wherein the target 3D structure comprises a staircase structure comprising multiple stair steps, and wherein at least one of the stair steps comprises at least one electrical contact, which is configured to connect between a respective memory array and a peripheral circuit.

9. The method according to claim 1, wherein the numbers of the layers to be removed form a sequence of powers of two.

10. A system for designing a patterning process for a three-dimensional (3D) memory, the system comprising:
an interface, which is configured to exchange information with one or more manufacturing tools; and
a processor, which is configured to define a target 3D structure of the 3D memory, to be applied in a periodic structure of layers on a substrate, to convert the target 3D structure into a sequence of multiple steps, each step specifying a respective pattern to be removed and a respective number of the layers to be removed from the periodic structure under the respective pattern, and to send, via the interface, the sequence of steps to the one or more manufacturing tools.

11. The system according to claim 10, wherein the periodic structure comprises two or more layers, and wherein at least two of the layers of the periodic structure differ in material composition.

12. The system according to claim 10, wherein the periodic structure comprises two or more layers, and wherein at least two of the layers of the periodic structure differ in material thickness.

13. The system according to claim 10, wherein at least two of the steps in the sequence specify different respective patterns.

14. The system according to claim 10, wherein at least two of the steps in the sequence specify different respective numbers of the layers to be removed.

15. The system according to claim 10, wherein the target 3D structure further comprises a reference target 3D structure having a respective reference sequence of multiple steps designed for producing the reference target 3D structure, and wherein the processor is configured to convert the reference target 3D structure by changing one or more properties of the steps of the reference sequence.

16. The system according to claim 15, wherein the processor is configured to change the properties by performing at least one of reordering the steps in the reference sequence, modifying the pattern to be removed in at least one step in the reference sequence, and changing the number of the layers to be removed in at least one step in the reference sequence.

17. The system according to claim 10, wherein the layers of the periodic structure implement multiple memory arrays, wherein the target 3D structure comprises a staircase structure comprising multiple stair steps, and wherein at least one of the stair steps comprises at least one electrical contact, which is configured to connect between a respective memory array and a peripheral circuit.

18. The system according to claim 10, wherein the numbers of the layers to be removed form a sequence of powers of two.

19. A non-transitory computer-readable medium including instructions that, when executed by one or more processors, cause the one or more processors to perform a method for designing a patterning process for a three-dimensional (3D) device, comprising:
defining a target 3D structure of the 3D device, to be applied in a periodic structure of layers on a substrate;
converting the target 3D structure into a sequence of multiple steps, each step specifying a respective pattern to be removed and a respective number of the layers to be removed from the periodic structure under the respective pattern; and
sending the sequence of steps to one or more manufacturing tools.

20. The non-transitory computer-readable medium of claim 19, wherein the 3D device comprises a 3D memory.
